(19) United States
(12) Patent Application Publication
(10) Pub. No.: US 2013/0175632 A1
(43) Pub. Date: Jul. 11, 2013

(54) REDUCTION OF CONTACT RESISTANCE AND JUNCTION LEAKAGE

(71) Applicants: Ming CAI, Hopewell Junction, NY (US); Dechao GUO, Fishkill, NY (US); Ahmet S. OZCAN, Pleasantville, NY (US); Liyang SONG, Wappingers Falls, NY (US); Chun-chen YEH, Clifton Park, NY (US)

(72) Inventors: Ming CAI, Hopewell Junction, NY (US); Dechao GUO, Fishkill, NY (US); Ahmet S. OZCAN, Pleasantville, NY (US); Liyang SONG, Wappingers Falls, NY (US); Chun-chen YEH, Clifton Park, NY (US)

(73) Assignee: INTERNATIONAL BUSINESS MACHINES CORPORATION, Armonk, NY (US)

(21) Appl. No.: 13/345,137

(22) Filed: Jan. 6, 2012

(51) Int. Cl. H01L 27/092; H01L 21/8238

(52) U.S. Cl. 257/369; 438/230; 257/E27.062; 257/E21.632

(57) ABSTRACT

A time clock clearly identifies where a user should position a time card therein. The clock and a printer platen are fixed relative to a base, and has the time card rests thereon. A printing mechanism moves relative to the base and has a target area, it is traversable between a print position and an idle position, and it impresses the time indicia onto the time card while in the print position. A ribbon shield is fixed relative to the base. A focused illuminated guide is fixed relative to the base, and in combination with the ribbon shield, guides the time card with respect to the printing mechanism to clearly identify where the user should position the time card in the time clock.

### FIELD OF THE INVENTION

The present invention generally relates to the field of semiconductors, and more particularly relates to forming silicide regions for a semiconductor device.

### BACKGROUND OF THE INVENTION

Silicide formation is of specific importance to integrated circuits, including those having complementary metal-oxide-semiconductor (CMOS) devices, because of the need to reduce the electrical resistance of the contacts (particularly at the source/drain and gate regions) in order to increase chip performance. Silicides are metal compounds that are thermally stable and provide for low electrical resistivity at the silicon/metal interface. Reducing contact resistance improves device speed, therefore increasing device performance.

### SUMMARY OF THE INVENTION

In one embodiment, a method for forming silicide regions on a metal-oxide-semiconductor device is disclosed. The method comprises forming a buried insulator layer on a substrate. A semiconductor layer is formed on the buried insulator layer. A first set of source/drain regions s formed in the semiconductor layer for an n-type metal-oxide-semiconductor (nMOS) device. A second set of source/drain regions is formed in the semiconductor layer for a p-type metal-oxide-semiconductor (pMOS) device. A first set of silicide regions is formed on at least the first set of source/drain regions. A second set of silicide regions is formed on at least the second set of source/drain regions. The first and second sets of silicide regions each comprise a first metallic material and a second metallic material. A percentage of the first metallic material in the first and second set of silicide regions is substantially the same. A percentage of the second metallic material in the second set of silicide regions is greater than the percentage of the second metallic material in the first set of silicide regions.

In another embodiment, another method for forming silicide regions on a metal-oxide-semiconductor device is disclosed. The method comprises forming a buried insulator layer on a substrate. A semiconductor layer is formed on the buried insulator layer. A first set of source/drain regions is formed in the semiconductor layer for an n-type metal-oxide-semiconductor (nMOS) device. A second set of source/drain regions is formed in the semiconductor layer for a p-type metal-oxide-semiconductor (pMOS) device. The first set of source/drain regions comprises a junction depth that is greater than a junction depth of the second set of source/drain regions. A first set of silicide regions is formed on at least the first set of source/drain regions. A second set of silicide regions is formed on at least the second set of source/drain regions. The first and second sets of silicide regions each comprise nickel and platinum. A percentage of the platinum ranges from 10.01% to 20%.

In yet another embodiment, a semiconductor device is disclosed. The semiconductor device comprises an n-type metal-oxide-semiconductor (nMOS) device and a p-type metal-oxide-semiconductor (nMOS) device. The nMOS device comprises a buried insulator layer formed on a substrate. A semiconductor layer is formed on the buried insulator layer. A first set of source/drain regions is formed in the semiconductor layer. A first set of silicide regions is formed on at least the first set of source/drain regions. The pMOS device comprises the buried insulator layer formed on the substrate. The pMOS device also comprises the semiconductor layer formed on the buried insulator layer. The pMOS device further comprises a second set of source/drain regions formed in the semiconductor layer, and a second set of silicide regions formed on at least the second set of source/drain regions. The first and second sets of silicide regions each comprise a first metallic material and a second metallic material. A percentage of the first metallic material in the first and second set of silicide regions is substantially the same. A percentage of the second metallic material in the second set of silicide regions is greater than the percentage of the second metallic material in the first set of silicide regions.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention, in which:

FIG. 1 is a cross-sectional view of a semiconductor structure after a gate structure and source/drain regions have been formed on a semiconductor substrate according to a first embodiment of the present invention;

FIG. 2 is a cross-sectional view of the semiconductor structure after a first metal layer has been formed on thereon according to the first embodiment of the present invention;

FIG. 3 is a cross-sectional view of the semiconductor structure after silicide regions have been formed thereon according to the first embodiment of the present invention;

FIG. 4 is a cross-sectional view of the semiconductor structure after a tensile stress liner and hard mask have been formed on the nMOS portion of the semiconductor structure and a second metal layer has been formed on both the nMOS portion a pMOS portion of the semiconductor structure according to the first embodiment of the present invention;

FIG. 5 is a cross-sectional view of the semiconductor structure after a tensile stress liner has been formed over the pMOS portion of the semiconductor structure according to the first embodiment of the present invention;

FIG. 6 is a cross-sectional view of the semiconductor structure after a trenches/openings have been formed within a dielectric layer deposited over the nMOS portion of the semiconductor structure according to a second embodiment of the present invention;

FIG. 7 is a cross-sectional view of the semiconductor structure after a trenches/openings have been formed within a dielectric layer deposited over the nMOS portion of the semiconductor structure according to the second embodiment of the present invention;

FIG. 8 is a cross-sectional view of the semiconductor structure after formation of silicide regions on the nMOS and pMOS portions of the semiconductor structure according to a third embodiment of the present invention;

FIG. 9 is an operational flow diagram illustrating one process for forming silicide regions according to one embodiment of the present invention; and

FIG. 10 is an operational flow diagram illustrating another process for forming silicide regions according to another embodiment of the present invention.

### DETAILED DESCRIPTION

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Standard metal salicidation typically experiences a variety of defects that can reach the p-n junction (if shallow enough). One type of defect is a pipe defect (or encroachment), which is localized overgrowth on existing defects in the silicon. Another type of defect is a divot defect, which comprises silicon/STI topography and edge effect. These defects can act as a leakage path if reaching the p-n junction. Therefore, one or more embodiments of the present invention utilizes a metal layer for forming silicide regions, where the metal layer comprises a first metal, such as nickel (Ni), and second metal, such as platinum (Pt), for simultaneously reducing contact resistance and junction leakage in both nMOS and pMOS devices. In one embodiment, the metal layer formed on the pMOS device comprises a higher percentage of the second metal than the metal layer formed on the nMOS device. In another embodiment, the percentage of the second metal in the metal layer formed on the pMOS and nMOS devices is substantially the same. However, the nMOS device comprises a greater junction depth than that of the pMOS device to prevent any defects resulting from the higher percentage of Pt in the nMOS device from going through the junction.

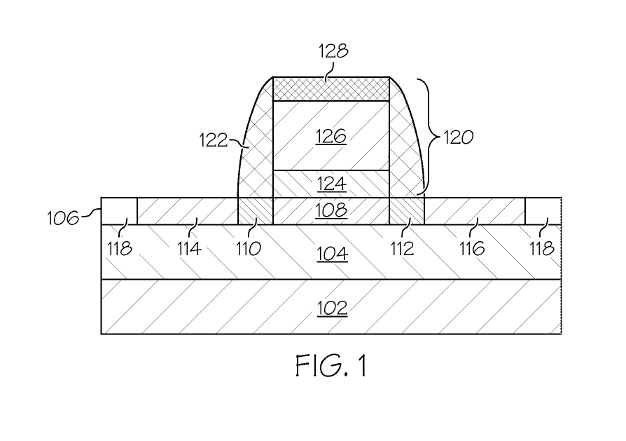

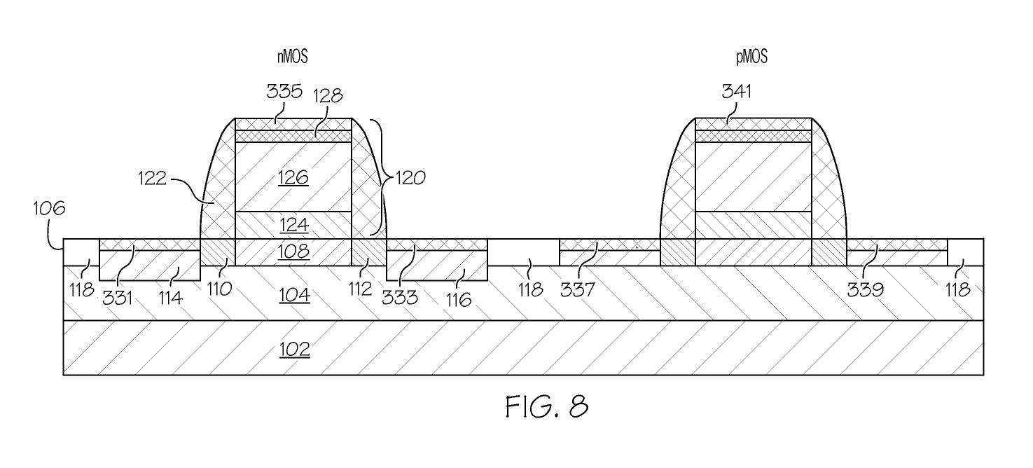

FIGS. 1-8 illustrate various processes for reducing contact resistance and junction leakage in a complementary metal-oxide-semiconductor (CMOS). It should also be noted that one or more embodiments of the present invention are applicable to both bulk substrate devices and silicon-on-insulator (SOI) devices. As shown in FIG. 1, there is provided a handle substrate 102, a buried insulator layer (e.g., buried oxide (BOX)) 104, and a top semiconductor layer 106. The handle substrate 102 can be a semiconductor substrate comprising a single crystalline semiconductor material such as single crystalline silicon, a polycrystalline semiconductor material, an amorphous semiconductor material, or a stack thereof. The thickness of the handle substrate 102 can be, for example, from 50 microns to 1,000 microns, although lesser and greater thicknesses can also be employed. A buried insulator layer 104 includes a dielectric material such as silicon oxide, silicon nitride, silicon oxynitride, or any combination thereof.

The thickness of the buried insulator layer 104 can be, for example, form 50 nm to 500 nm, although lesser and greater thicknesses can also be employed. The thickness of the top semiconductor layer 106 can be, for example, from 3 nm to 60 nm, and typically from 5 nm to 10 nm, although lesser and greater thicknesses can also be employed. The top semiconductor layer 106 can comprise any semiconducting material, including but not limited to Si (silicon), strained Si, SiC (silicon carbide), Ge (geranium), SiGe (silicon germanium), SiGeC (silicon-germanium-carbon), Si alloys, Ge alloys, GaAs (gallium arsenide), InAs (indium arsenide), InP (indium phosphide), any combination thereof, as well as other III/V or II/VI compound semiconductors and alloys thereof. Also, each of the nMOS and pMOS devices can include top semiconductor layer 106 with different materials.

FIG. 1 shows that the top semiconductor layer 106 includes various single crystalline semiconductor portions, which can comprise, for example, a body/channel region 108, a source extension region 110, a drain extension region 112, a planar source region 114, and a planar drain region 116. Shallow trench isolation structures 118 can be formed in the top semiconductor layer 106 employing conventional fabrication methods. For example, the shallow trench isolation structures 118 can be formed by trenches extending from the top surface of the top semiconductor layer 106 at least to the top surface of the buried insulator layer 104, filling the trenches with a dielectric material, and removing excess dielectric material from above the top surface of the top semiconductor layer 106.

The various single crystalline semiconductor portions (108, 110, 112, 114, 116) in the top semiconductor layer 106 can be formed by introducing electrical dopants such as B, Ga, In, P, As, and/or Sb by ion implantation, plasma doping, and/or gas phase doping employing various masking structures as known in the art. Before implanting electrical dopants into various portions of the top semiconductor layer 106, a gate stack structure 120 and gate spacer 122 are formed. The gate stack 120 is formed on the semiconductor layer 106 over the body region 108. In one embodiment, the gate stack 120 comprises a gate dielectric 124 and a gate conductor 126. In the illustrated embodiment, a gate polysilicon cap 128 is deposited on the gate conductor layer 126, such as through LPCVD or silicon sputtering. It should be noted that instead of first forming the gate stack 120, a conventional reverse metal gate process (RMG) can be utilized for forming the gate structure 120.

The gate stack 120 can be formed by depositing a stack of a gate dielectric material and a gate conductor material on the top semiconductor layer 106. This stack is then patterned and etched to form the gate dielectric 124 and the overlying gate conductor 126 on a portion of the top semiconductor layer 106. The gate dielectric 124 of this embodiment is a conventional dielectric material (such as silicon oxide, silicon nitride, silicon oxynitride, or a stack thereof) that is formed by thermal conversion of a top portion of the active region and/or by chemical vapor deposition (CVD). In an alternative embodiment, the gate dielectric 124 is a high-k dielectric material (such as hafnium oxide, zirconium oxide, lanthanum oxide, aluminum oxide, titanium dioxide, strontium titanate, lanthanum aluminate, yttrium oxide, an alloy thereof, or a silicate thereof) that is formed by CVD, atomic layer deposition (ALD), molecular beam epitaxy (MBE), pulsed laser deposition (PLD), liquid source misted chemical deposition (LSMCD), or physical vapor deposition (PVD). Alternatively, the gate dielectric may comprise any suitable combination of those dielectric materials.

The gate conductor 126 is a semiconductor (e.g., polysilicon) gate layer and/or a metal gate layer. For example, the gate dielectric 124 can be a conventional dielectric material and the gate conductor 126 can be a semiconductor gate layer. Alternatively, the gate dielectric 124 can be a high-k dielectric material and the gate conductor 126 can be a metal gate layer of a conductive refractory metal nitride (such as tantalum nitride, titanium nitride, tungsten nitride, titanium aluminum nitride, triazacyclononane, or an alloy thereof). In a further embodiment, the gate conductor 126 comprises a stack of a metal gate layer and a semiconductor gate layer. The gate stack 120 can also include a work function metallic layer as well. In yet a further embodiment, the gate stack 120 can be formed atop an optional chemical oxide layer (not shown) (also referred to herein as an “interfacial layer”), which is formed on an exposed semiconductor surface of the body portion 108 of the top semiconductor layer 106.

The gate spacer 122 comprises a dielectric material (such as silicon oxide, silicon nitride, silicon oxynitride or any combination of these). The gate spacer 122 is formed on gate stack 120 and on a portion of the top semiconductor layer 106. In one embodiment, a reactive-ion etch process is used to remove the dielectric material on horizontal surfaces such as the top of the gate stack 120, the STI regions 118, and portions of the top semiconductor layer 106 to form a gate spacer only on the sidewall of the gate structure 120. However, the gate spacer material can be etched such that the gate spacer 122 also resides on top of the gate structure 120 as well.

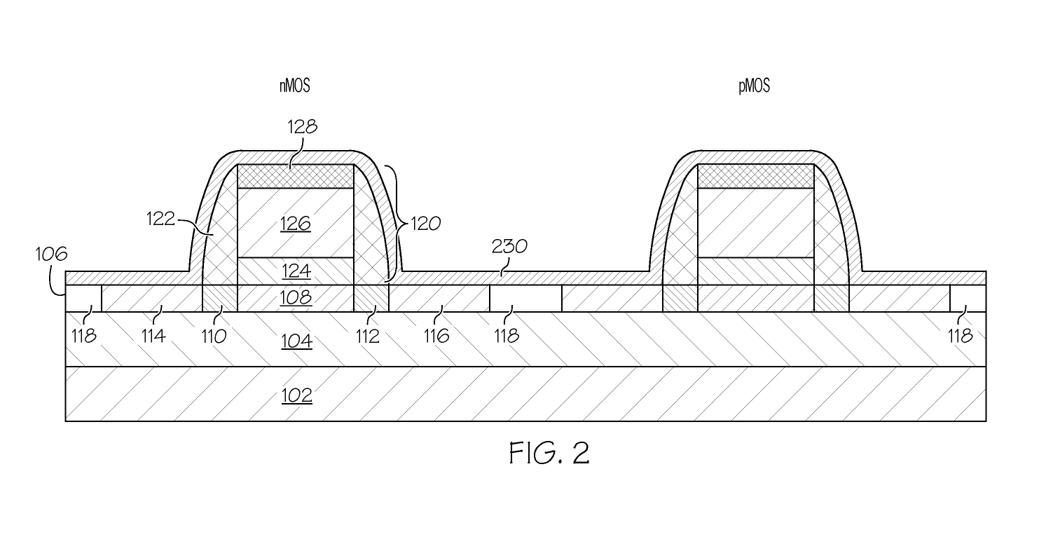

FIG. 2 shows that a first metal layer 230 is formed over the entire wafer. The metal layer 230 can be formed by chemical vapor deposition (CVD), physical vapor deposition (PVD), atomic layer deposition (ALD), or any combination thereof. In one embodiment, the metal layer 230 comprises a first metal and a second metal. In this embodiment, the first metal is Ni and the second metal is Pt. The percentage of Pt can range, for example, from 1% to 15%. The incorporation of Pt into NiSi delays both the agglomeration of NiSi and the formation of NiSi₂. This extends the temperature range over which NiSi exists. Also, Pt is a material with a high Schottky barrier height (˜0.8 eV) with respect to n-type Si.

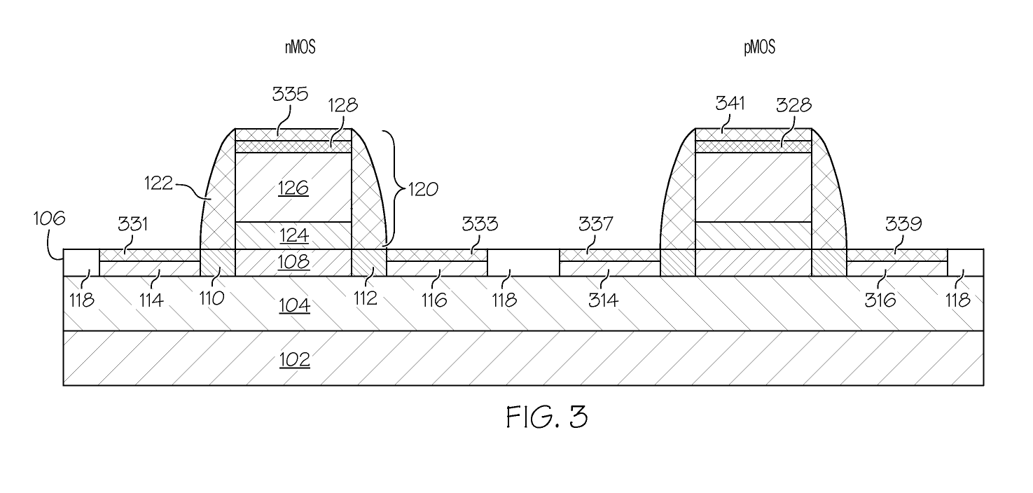

An anneal process, such as a rapid thermal anneal (RTA), is performed to form silicide, such as (but not limited to) NiSi with Pt, on both devices. FIG. 3 shows that portions of the metal layer 230 are then selectively removed (e.g., through an aqua regia wet etch) from non-active regions while leaving the silicide untouched. For example, FIG. 3 shows that silicide regions 331, 333, 335, 337, 339, 341 remain atop active regions such as the source/drain regions 114, 116, 314, 316 and the gate polysilicon cap 128, 328 of both the nMOS and pMOS devices, respectively. These silicide regions 331, 333, 335, 337, 339, 341, in this embodiment, comprise NiSi with a percentage of Pt ranging from 1% to 10%.

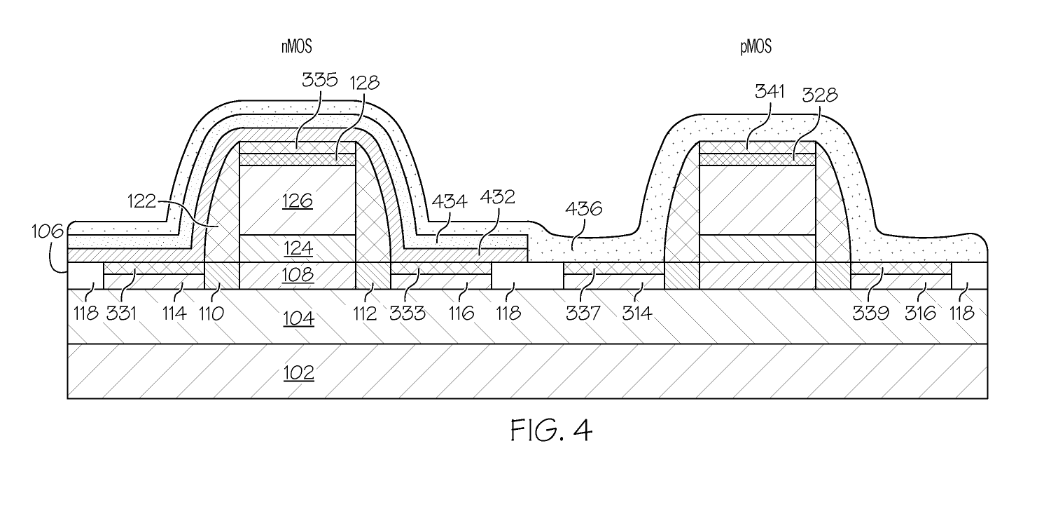

A tensile stress liner 432 and a hard mask 434 are then formed over the nMOS device. For example, FIG. 4 shows that the tensile stress liner 432 has been formed atop silicide regions 331, 333, 335 formed atop the source/drain regions 114, 116 and the polysilicon cap 128. FIG. 4 also shows that the tensile stress liner 432 has also been formed over the gate spacer 122 and a portion of the STI regions 118. FIG. 4 further shows that the hard mask 434 has been formed over the tensile stress liner 432. In one embodiment, the tensile stress liner 432 is formed by depositing an intrinsic tensile-stressed liner material such as, but not limited to silicon nitride or ultra-violet (UV) cured silicon nitride film with enhanced strain level. The hard mask 434 can comprise a dielectric material composed of a nitride, oxide, oxynitride material, and/or any other suitable dielectric layer.

Various methods now known or later developed can be used for depositing the tensile-stressed liner material and hard mask material. Examples of some of these methods are chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

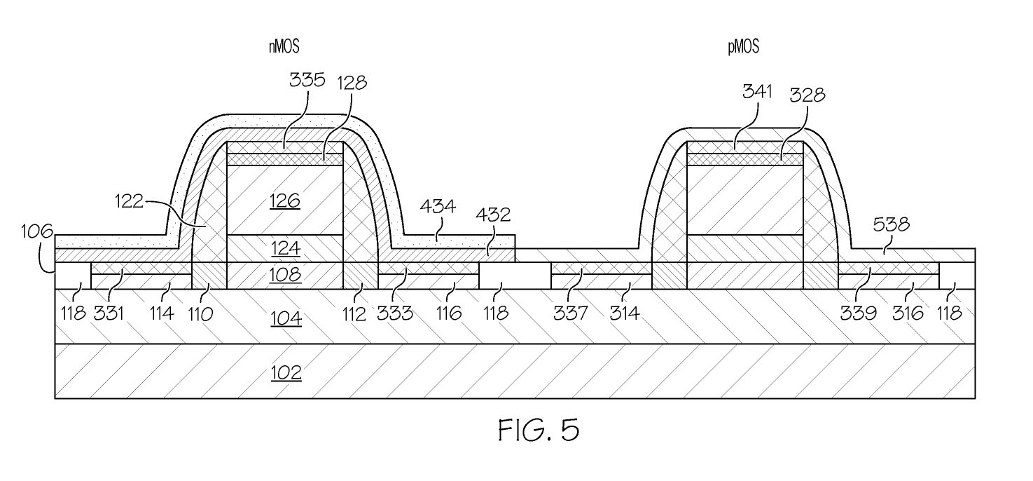

Any tensile stress liner material and hard mask material that has been formed over the pMOS device is removed. A second metal layer 436 is formed over the wafer as shown in FIG. 4. The second metal layer 436 can be formed by chemical vapor deposition (CVD), physical vapor deposition (PVD), atomic layer deposition (ALD), or any combination thereof. In one embodiment, this metal layer 436 comprises substantially the same metal as the second metal of the first metal layer 230. For example, in this embodiment, the second metal layer 436 comprises Pt. Another anneal process, such as a rapid thermal anneal (RTA), is performed resulting in the silicide regions 337, 339, 341 of the pMOS device having a higher percentage of Pt than the silicide regions 331, 333, 335 of the nMOS device. For example, the silicide regions 337, 339, 341 of the pMOS device comprise a percentage of Pt ranging from 10.01% to 20%. Portions of the second metal layer 436 are then selectively removed from non-active regions while leaving the silicide regions 337, 339, 341 of the pMOS device untouched, as shown in FIG. 5. For example, FIG. 5 shows that after the selectively etching process silicide regions 337, 339, 341 remain atop active regions such as the source/drain regions 314, 316 and the gate polysilicon cap 328 of pMOS device.

A compressive stress liner 538 is then formed over the pMOS device. For example, FIG. 5 shows that the compressive stress liner 538 has been formed atop the silicide regions 337, 339, 341 of the source/drain regions 314, 316 and the polysilicon cap 328 of the pMOS device. FIG. 5 also shows that the compressive stress liner 538 has also been formed over the gate spacer 122 and a portion of the STI regions 118 of the pMOS device. In one embodiment, the compressive stress liner 538 is formed by depositing an intrinsic tensile-stressed liner material such as, but not limited to silicon nitride. The compressive stress liner material can be deposited using any of the methods discussed above with respect to the tensile stress liner. Any compressive stress liner material and hard mask material that has been formed over the nMOS device is removed from the nMOS device. The hard mask 434 on the nMOS device can also be removed as well.

From this point, conventional fabrication processes are used to form the remainder of the integrated circuit that includes this transistor. The resulting structure comprises a pMOS device with a higher percentage of Pt in the silicide regions than the percentage of Pt in the silicide regions of the nMOS device. The addition of Pt in the silicide regions reduces the contact resistance and junction leakage in both the nMOS and pMOS devices. By increasing the percentage of Pt for the pMOS device, as compared to the nMOS device, the contact resistance of the pMOS device can be reduced by, in one embodiment, approximately 20-30%.

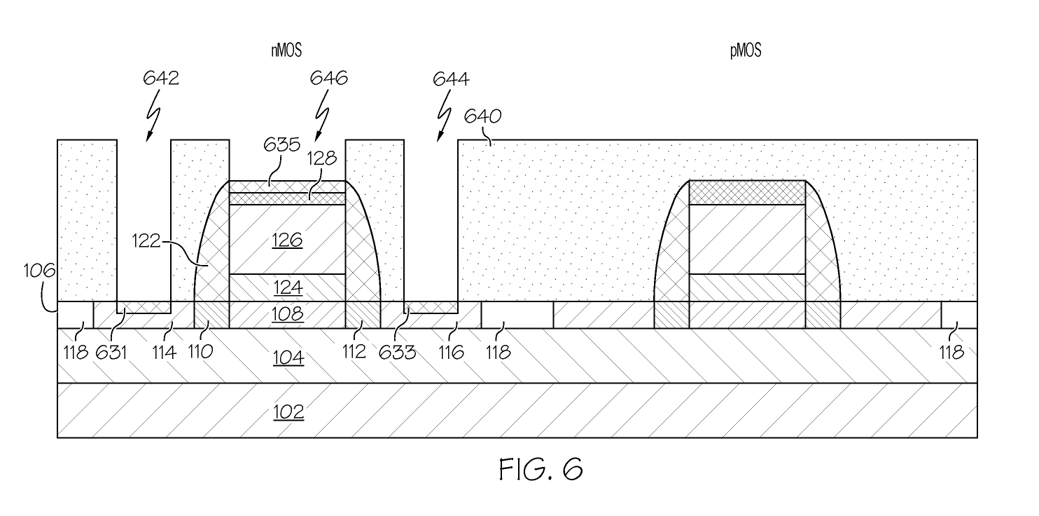

In another embodiment, an RMG process can be utilized to form the gate structure 120, as discussed above. In this embodiment a dielectric layer 640 is formed during the RMG process. The dielectric layer 640 covers the entire wafer and extends above the gate spacer 120, 320 of both devices, as shown in FIG. 6. In one embodiment, the dielectric layer 640 can be a flowable oxide, a high-density plasma (HDP) oxide etc. FIG. 6 further shows that after the gate structure 122 has been formed portions of the dielectric layer 640 over the source/drain regions 114, 116 of the nMOS device are removed (e.g., through a dry etch such as RIE and/or a wet etch using HF) so as to create trenches/openings 642, 644, 646. These trenches/openings 642, 644, 646 expose at least a portion of the source/drain regions 114, 116 and the gate polysilicon cap 128. A first metal layer is then formed over the entire wafer as discussed above with respect to FIG. 2. In this embodiment, the metal layer comprises a first metal and a second metal such as Ni and Pt, respectively. The percentage of Pt can range from 1% to 10%. An anneal process, such as a rapid thermal anneal (RTA), is performed to form silicide regions 631, 633, 635 on active areas of the nMOS device. It should be noted that in another embodiment, the gate can be filled with another material such as, but not limited to, Aluminum, to set the work function. In this embodiment, silicide is not formed on the gate.

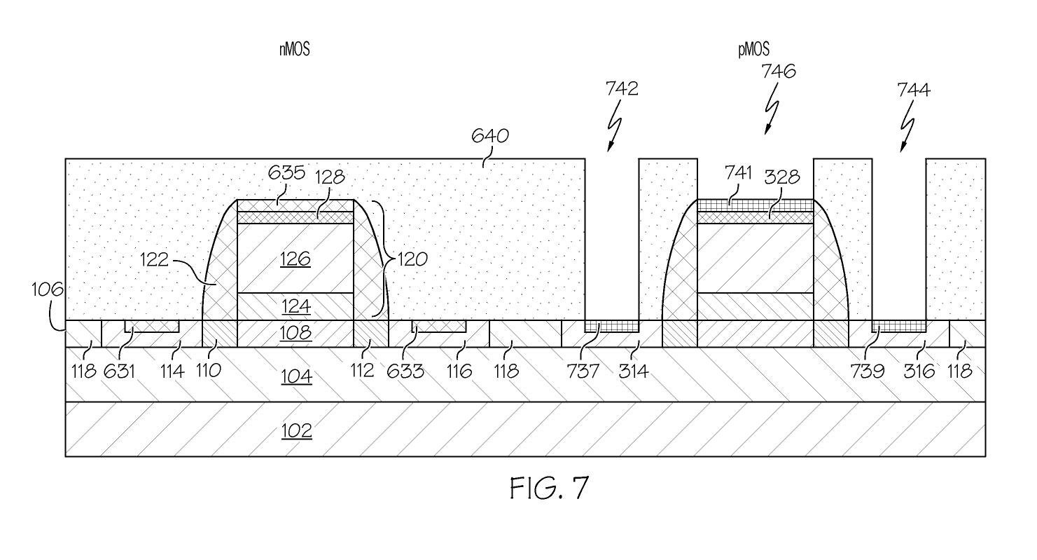

Portions of the metal layer are then selectively removed (e.g., through an aqua regia wet etch) from non-active regions while leaving the silicide regions 631, 633, 635 untouched. For example, FIG. 6 shows that silicide regions 631, 633, 635 remain atop active regions such as the source/drain regions 114, 116 and the gate polysilicon cap 128 the nMOS device. In this embodiment, these silicide regions 631, 633, 635 comprise NiSi with a percentage of Pt ranging from 1% to 10%. The trenches/openings 642, 644, 646 are then filed with a dielectric material. For example, a hard mask material is deposited on the nMOS device filling the trench openings 642, 644, 646, as shown in FIG. 7. In one embodiment, the hard mask material comprises a dielectric material composed of a nitride, oxide, oxynitride material, and/or any other suitable dielectric layer.

Portions of the dielectric layer 640 over the source/drain regions 314, 316 of the pMOS device are removed (e.g., through a dry etch such as RIE and/or a wet etch using HF) so as to create trenches/openings 742, 744, 746. These trenches/openings 742, 744, 746 expose at least a portion of the source/drain regions 314, 316 of the pMOS device, as shown in FIG. 7. A second metal layer is formed over the pMOS device. The second metal layer can be formed using the same process discussed above with respect to FIG. 4. In this embodiment, the second metal layer comprises a first metal and a second metal such as Ni and Pt, respectively. However, the percentage of Pt in the second metal layer is higher than the percentage of platinum in the first metal layer used to form the silicide regions 631, 633, 635 of the nMOS device. For example, the percentage of Pt in the second metal layer can range from 10.01% to 20%.

An anneal process, such as a rapid thermal anneal (RTA), is performed to form silicide regions 737, 739, 741 on the pMOS device with a higher percentage of Pt than the silicide on the nMOS device. For example, the percentage of Pt in the silicide regions 737, 739, 741 of the pMOS device is 10.01% to 20% and the percentage of Pt in the silicide regions 631, 633, 635 of the nMOS device is 1% to 10%. It should be noted that in another embodiment, the trenches/openings for both the nMOS device and pMOS device can be filled with another material such as, but not limited to, Aluminum, to set the work function. In this embodiment, silicide is not formed. Portions of the second metal layer are then selectively removed (e.g., through an aqua regia wet etch) from non-active regions while leaving the silicide regions 737, 739, 741 untouched. For example, FIG. 7 shows that silicide regions 737, 739, 741 remain atop active regions such as the source/drain regions 314, 316 and the gate polysilicon cap 328 the pMOS device. From this point, conventional fabrication processes are used to form the remainder of the integrated circuit that includes this transistor.

In another embodiment, the silicide regions of the nMOS device can comprise substantially the same high percentage (e.g., 10.01% to 20%) of Pt as the silicide regions of the pMOS device. In this embodiment, the implantation process that is performed to form the source/drain regions 114, 116 of the nMOS device is a deep implantation process. This results in implant regions of the nMOS device having a depth that is greater than the implant regions of the pMOS device. In one embodiment, the implant regions of the nMOS device can be above, below, or stop on the boundary between the buried insulator layer 104 and the semiconductor layer 106. Therefore, any NiSi silicide related defects experienced by the nMOS device as a result of the high percentage of Pt are prevented from going through the junction.

In this embodiment, only a first metal layer needs to be deposited in the embodiments discussed above with respect to FIGS. 2-7. However, this metal layer comprises a percentage of Pt ranging from 10.01% to 20% as compared to 1% to 10%. If an RMG process is used to form the gate structure 120, as discussed above with respect to FIGS. 6-7, trench openings can be formed for both the nMOS and pMOS devices during the same processing step. Then, only a first metal layer needs to be deposited with a percentage of Pt ranging from 10.01% to 20%. The silicide regions for both devices can then be formed during the same anneal processing step.

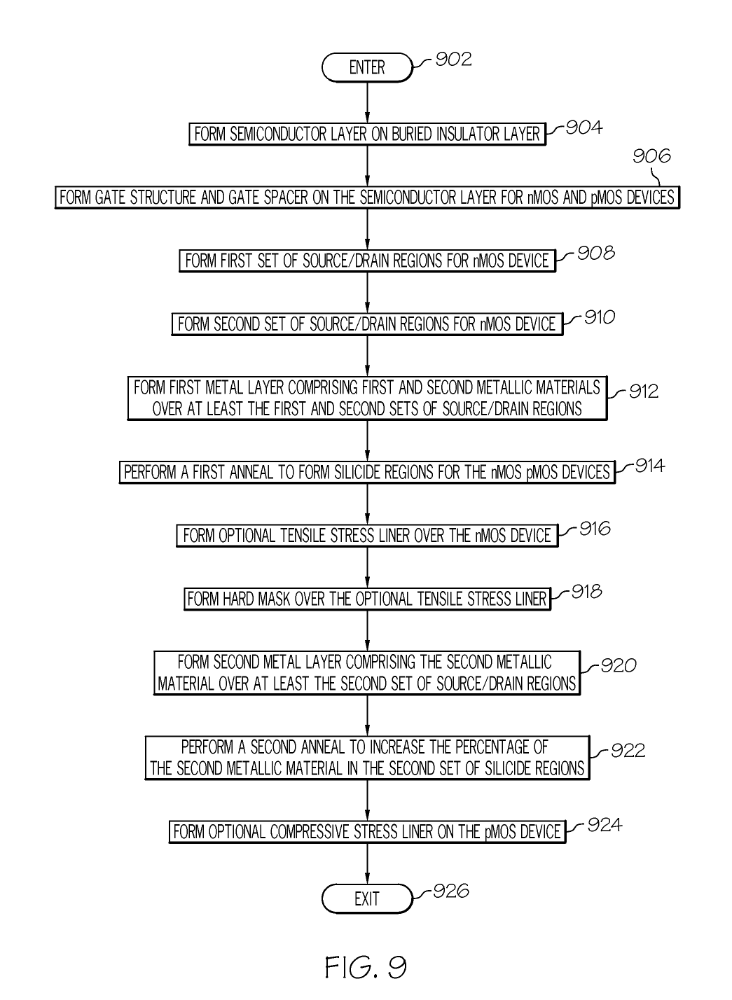

FIG. 9 is an operational flow diagram illustrating one process for forming silicide regions on a semiconductor device according to one embodiment of the present invention. In FIG. 9, the operational flow diagram begins at step 902 and flows directly to step 904. It should be noted that each of the steps shown in FIG. 9 has been discussed in greater detail above with respect to FIGS. 1-5. A semiconductor layer 106, at step 904, is formed on a buried insulator layer 104. A gate structure 120 and gate spacer 122, at step 906, are formed on the semiconductor layer 106 for an n-type device and a p-type device. A first set of source/drain regions 114, 116, at step 908, is formed in the semiconductor layer 106 for the nMOS device. A second set of source/drain regions 314, 316, at step 910, is formed in the semiconductor layer 106 for the pMOS device.

A first metal layer 230, at step 912, comprising a first and second metallic material (e.g., Ni and Pt) is over at least the source/drain regions 114, 116, 314, 316 (and optionally the capping layers 128, 328) of the nMOS and pMOS devices. A first anneal, at step 914, is performed to form a first set of silicide regions 331, 333, 335 on the first set of source/drain regions 114, 116, a second set of silicide regions 337, 339, 341 on the second set of source/drain regions 314, 316, and optional the capping layers 128, 328 of the nMOS and pMOS devices. An optional tensile stress liner 432, at step 916, is formed over the nMOS device. A hard mask 434, at step 918, is formed over the tensile liner 432.

A second metal layer 436, at step 920, comprising the second metallic material (e.g., Pt) is formed over at least the source/drain regions 314, 316 (and optionally the capping layers 328) of the pMOS device. A second anneal, at step 922, is performed to increase the percentage of the second metallic material in the second set of silicide regions 337, 339, 341 of the pMOS device. An optional compressive stress liner 538, at step 924, is formed over the pMOS device. From this point, conventional fabrication processes are used to form the remainder of the integrated circuit that includes this transistor. The control flow then exits at step 926. It should be noted that in another embodiment only the first metal layer 230 is required to be deposited with a high percentage (e.g., 10.01% to 20%) of the second metal. In this embodiment, the implant regions for source/drain regions 114, 116 of the nMOS device have a greater depth than the implant regions for the source/drain regions 314, 316 of the pMOS device.

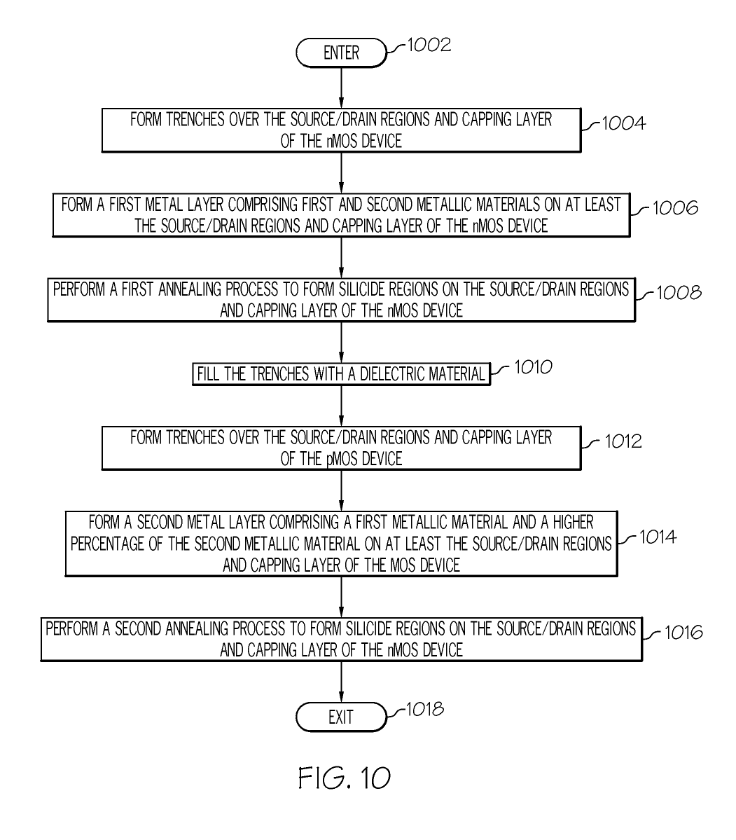

FIG. 10 is an operational flow diagram illustrating another process for forming silicide regions on a semiconductor device according to another embodiment of the present invention. In FIG. 10, the operational flow diagram begins at step 1002 and flows directly to step 1004. It should be noted that each of the steps shown in FIG. 10 has been discussed in greater detail above with respect to FIGS. 6-7. It should also be noted that the process steps of FIG. 10 begin after the gate structure 120 has been formed using a replacement metal gate processing flow. Trenches 642, 644, 646, at step 1004, are formed in the dielectric layer 640 over the source/drain regions 114, 116 and capping layer 128 of the nMOS device. A first metal layer comprising a first and second metallic material (e.g., Ni and Pt), at step 1006, is formed over at least the source/drain regions 114, 116 and capping layer 128 of the nMOS device. A first annealing process, at step 1008, is performed to form silicide regions 631, 633, 635 on the source/drain regions 114, 116 and capping layer 128 of the nMOS device. The trenches 642, 644, 646, at step 1010, are filled with a dielectric material. From this point, conventional fabrication processes are used to form the remainder of the integrated circuit that includes this transistor.

Trenches 742, 744, 746, at step 1012, are formed in the dielectric layer 640 over the source/drain regions 314, 316 and capping layer 328 of the pMOS device. A second metal layer comprising a first and second metallic material (e.g., Ni and Pt), at step 1014, is formed over at least the source/drain regions 314, 316 and capping layer 328 of the pMOS device. The second metal layer comprises a higher percentage of the second metallic material than the percentage of the second metallic material in the first metal layer. A second annealing process, at step 1016, is performed to form silicide regions 737, 730, 741 on the source/drain regions 314, 316 and capping layer 328 of the pMOS device. From this point, conventional fabrication processes are used to form the remainder of the integrated circuit that includes this transistor. The control flow then exits at step 1018.

It should be noted that some features of the present invention may be used in an embodiment thereof without use of other features of the present invention. As such, the foregoing description should be considered as merely illustrative of the principles, teachings, examples, and exemplary embodiments of the present invention, and not a limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above are used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product or electronic device that includes integrated circuit chips, ranging from toys and other low-end applications to advanced computer products having a display, a keyboard, or other input device, and a central processor.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for forming silicide regions on a metal-oxide-semiconductor device, the method comprising:
forming a buried insulator layer on a substrate;
forming a semiconductor layer on the buried insulator layer;
forming a first set of source/drain regions in the semiconductor layer for an n-type metal-oxide-semiconductor (nMOS) device;
forming a second set of source/drain regions in the semiconductor layer for a p-type metal-oxide-semiconductor (pMOS) device; and
forming a first set of silicide regions on at least the first set of source/drain regions and a second set of silicide regions on at least the second set of source/drain regions, wherein the first and second sets of silicide regions each comprise a first metallic material and a second metallic material, wherein a percentage of the first metallic material in the first and second set of silicide regions is substantially the same, and wherein a percentage of the second metallic material in the second set of silicide regions is greater than the percentage of the second metallic material in the first set of silicide regions.

2. The method of claim 1, wherein forming the first set of silicide regions and the second set of silicide regions comprises:
forming a first metal layer comprising the first and second metallic materials over at least the first and second sets of source/drain regions;
performing a first anneal to form the first and second sets of silicide regions;
forming a masking layer over the nMOS device;
forming, after forming the masking layer, a second metal layer comprising the second metallic material over at least the second set of source/drain regions; and
performing a second anneal, wherein the second anneal increases the percentage of the second metallic material in the second set of silicide regions.

3. The method of claim 1, further comprising:
forming, prior to forming the first and second set of silicide regions for each of the nMOS device and pMOS device:
a replacement gate structure on the semiconductor layer for each of the nMOS device and pMOS device;
a gate spacer around each of the replacement gate structure;
a dielectric layer over the nMOS device and pMOS device;
removing, after forming the dielectric layer, the replacement gate structure so as to form a cavity within the dielectric layer exposing a portion of the semiconductor layer; and
forming a gate structure comprising a gate dielectric, a gate conductor, and a capping layer on the exposed portion of the semiconductor layer.

4. The method of claim 3, wherein forming the first set of silicide regions comprises:
forming, after forming the gate structure, a first set of trenches within the dielectric layer over the first set of source/drain regions and the capping layer of the nMOS device, wherein the first set of trenches exposes at least a portion of the first set of source/drain regions and the capping layer of the nMOS device;
forming a first metal layer comprising the first and second metallic materials within the first set of trenches over at least the first set of source/drain regions and the capping layer; and
performing a first anneal to form the first set of silicide regions.

5. The method of claim 4, wherein forming the second set of silicide regions comprises:
filling, after forming the first set of silicide regions, the first set of trenches with a dielectric material;
forming, after filling the first set of trenches with the dielectric material, a second set of trenches within the dielectric layer over the second set of source/drain regions and the capping layer of the pMOS device, wherein the second set of trenches exposes at least a portion of the second set of source/drain regions and the capping layer of the pMOS device;
forming a second metal layer comprising the first and second metallic materials within the second set of trenches over at least the second set of source/drain regions and the capping layer, wherein the second metallic material in the second metal layer comprises a higher percentage of the second metallic material than a percentage of the second metallic material in the first metal layer; and
performing a second anneal to form the second set of silicide regions.

6. The method of claim 1, wherein the first metallic material is nickel and the second metallic material is platinum.

7. The method of claim 1, further comprising:
forming for each of the nMOS device and pMOS device
a gate dielectric on the semiconductor layer;
a gate conductor on the gate dielectric;
a capping layer on the gate dielectric; and
a gate spacer around the gate dielectric, the gate conductor, and the capping layer.

8. The method of claim 7, wherein forming the first set of silicide regions on at least the first set of source/drain regions comprises:
forming a silicide region in the first set of silicide regions on the capping layer of the nMOS device.

9. The method of claim 8, wherein forming the second set of silicide regions on at least the second set of source/drain regions comprises:
forming a silicide region in the second set of silicide regions on the capping layer of the pMOS device.

10. A method for forming silicide regions on a metal-oxide-semiconductor device, the method comprising:
forming a buried insulator layer on a substrate;
forming a semiconductor layer on the buried insulator layer;
forming a first set of source/drain regions in the semiconductor layer for an n-type metal-oxide-semiconductor (nMOS) device;
forming a second set of source/drain regions in the semiconductor layer for a p-type metal-oxide-semiconductor (pMOS) device, wherein the first set of source/drain regions comprises a junction depth that is greater than a junction depth of the second set of source/drain regions; and
forming a first set of silicide regions on at least the first set of source/drain regions and a second set of silicide regions on at least the second set of source/drain regions, wherein the first and second sets of silicide regions each comprise nickel and platinum, wherein a percentage of the platinum ranges from 10.01% to 20%.

11. The method of claim 10, wherein forming the first set of silicide regions and the second set of silicide regions comprises:
forming a metal layer comprising the nickel and the platinum over at least the first and second sets of source/drain regions; and
performing an anneal to form the first and second sets of silicide regions.

12. The method of claim 10, further comprising:
forming, prior to forming the first and second set of silicide regions for each of the nMOS device and pMOS device:
a replacement gate structure on the semiconductor layer for each of the nMOS device and pMOS device;
a gate spacer around each of the replacement gate structure;
a dielectric layer over the nMOS device and pMOS device;
removing, after forming the dielectric layer, the replacement gate structure so as to form a cavity within the dielectric layer exposing a portion of the semiconductor layer; and
forming a gate structure comprising a gate dielectric, a gate conductor, and a capping layer on the exposed portion of the semiconductor layer.

13. The method of claim 12, wherein forming the first set of silicide regions and the second set of silicide regions comprises:
forming, after forming the gate structure for the nMOS device, a first set of trenches within the dielectric layer over the first set of source/drain regions and the capping layer of the nMOS device, wherein the first set of trenches exposes at least a portion of the first set of source/drain regions and the capping layer of the nMOS device;
forming, after forming the gate structure for the pMOS device, a second set of trenches within the dielectric layer over the second set of source/drain regions and the capping layer of the pMOS device, wherein the second set of trenches exposes at least a portion of the second set of source/drain regions and the capping layer of the pMOS device;
forming a metal layer comprising the nickel and the platinum within the first set of trenches and the second set of trenches, wherein the metal layer is formed over at least the first set of source/drain regions, the second set of source/drain regions, and the capping layers of each of the nMOS device and the pMOS device; and
performing an anneal to form the first set of silicide regions and the second set of silicide regions.

14. A semiconductor device comprising:
an n-type metal-oxide-semiconductor (nMOS) device comprising:
a buried insulator layer formed on a substrate;
a semiconductor layer formed on the buried insulator layer;
a first set of source/drain regions formed in the semiconductor layer; and
a first set of silicide regions formed on at least the first set of source/drain regions; and
a p-type metal-oxide-semiconductor (nMOS) device comprising:
the buried insulator layer formed on the substrate;
the semiconductor layer formed on the buried insulator layer;
a second set of source/drain regions formed in the semiconductor layer; and
a second set of silicide regions formed on at least the second set of source/drain regions,
wherein the first and second sets of silicide regions each comprise a first metallic material and a second metallic material, wherein a percentage of the first metallic material in the first and second set of silicide regions is substantially the same, and wherein a percentage of the second metallic material in the second set of silicide regions is greater than the percentage of the second metallic material in the first set of silicide regions.

15. The semiconductor device of claim 14, wherein each of the nMOS device and the pMOS device further comprises:
a gate structure formed on the semiconductor layer, wherein the gate structure comprises a gate dielectric, a gate conductor, and a capping layer.

16. The semiconductor device of claim 14, wherein the first metallic material is nickel and the second metallic material is platinum.

17. A semiconductor device comprising:
an n-type metal-oxide-semiconductor (nMOS) device comprising:
a buried insulator layer formed on a substrate;
a semiconductor layer formed on the buried insulator layer;
a first set of source/drain regions formed in the semiconductor layer; and
a first set of silicide regions formed on at least the first set of source/drain region; and
a p-type metal-oxide-semiconductor (nMOS) device comprising:
the buried insulator layer formed on the substrate;
the semiconductor layer formed on the buried insulator layer;
a second set of source/drain regions formed in the semiconductor layer; and
a second set of silicide regions formed on at least the second set of source/drain regions,
wherein the first set of source/drain regions comprises a junction depth that is greater than a junction depth of the second set of source/drain regions, and wherein the first and second sets of silicide regions each comprise nickel and platinum, wherein a percentage of the platinum ranges from 10.01% to 20%.

18. The semiconductor device of claim 17, wherein each of the nMOS device and the pMOS device further comprises:
a gate structure formed on the semiconductor layer, wherein the gate structure comprises a gate dielectric, a gate conductor, and a capping layer.
